(19) United States
(12) Patent Application Publication
(10) Pub. No.: US 2018/0105933 A1
(43) Pub. Date: Apr. 19, 2018

(54) SUBSTRATE PROCESSING APPARATUS AND METHOD FOR CLEANING CHAMBER

(71) Applicant: EUGENE TECHNOLOGY CO., LTD., Yongin-Si, Gyeonggi-Do (KR)

(72) Inventors: Woo Duck JUNG, Suwon-Si, Gyeonggi-Do (KR); Sung Tae JE, Yongin-Si, Gyeonggi-Do (KR); Kyu Jin CHOI, Yongin-Si, Gyeonggi-Do (KR); Ja Dae KU, Suwon-Si, Gyeonggi-Do (KR); Jun KIM, Yongin-Si, Gyeonggi-Do (KR)

(21) Appl. No.: 15/566,698

(22) PCT Filed: Apr. 19, 2016
(86) PCT No.: PCT/KR2016/004075

§ 371 Date: Oct. 13, 2017

(30) Foreign Application Priority Data
Apr. 21, 2015 (KR) 10-2015-0055991

(51) Int. Cl. C23C 16/44; C23C 16/455; H01L 21/67; H01L 21/687

(52) U.S. Cl. CPC C23C 16/4405; H01L 21/68792; H01L 21/67063; C23C 16/45502

(57) ABSTRACT

Provided is a substrate processing apparatus. The substrate processing apparatus includes a chamber including a first body part configured to provide a space in which substrates stand by and a second body part configured to provide a space in which a thin film deposition process is performed on each of the substrates, a substrate holder on which the substrates are stacked, the substrate holder being movable between the first body part and the second body part, a first supply unit configured to supply a first gas for depositing a thin film on the substrate in the second body part, a second supply unit configured to supply a second gas, which reacts with by-products generated while the thin film is deposited to generate fume, into the first body part, and an exhaust unit configured to exhaust the gases within the chamber. Thus, by-products generated while the thin film is deposited may be quickly removed.

### TECHNICAL FIELD

The present disclosure relates to a substrate processing apparatus and a method of cleaning a chamber, and more particularly, to a substrate processing apparatus that is capable of quickly removing by-products generated in a chamber while a thin film is deposited on a substrate and a method of cleaning the chamber.

### BACKGROUND ART

In general, semiconductor devices are manufactured by depositing various materials in a thin film shape on a substrate to pattern the deposited thin film. For this, several stages of different processes such as a deposition process, an etching process, a cleaning process, and a drying process are performed.

A selective epitaxial process of these processes may be a process in which a silicon raw gas or an etching gas is supplied into a chamber in which a substrate is accommodated to grow a thin film on the substrate. There is a gas containing Cl components among the gases that are used for the selective epitaxial process. Thus, after the selective epitaxial process is performed, by-products such as the Cl components may remain in the chamber of a substrate processing apparatus.

When the inside of the chamber is opened immediately, the Cl components remaining as the by-products in the chamber may react with air introduced into the chamber to suddenly generate a large amount of fume. The fume discharged to the outside of the chamber may cause environmental pollution, corrosion of equipment, safety accidents, and the like. Thus, when the chamber is inspected or repaired, the chamber has to be opened after a cleaning process for removing the by-products within the chamber is performed.

In accordance with the related art, an inert gas has been supplied into the chamber for a long time before the inside of the chamber is opened to remove the by-products remaining the chamber. However, the process for removing the by-products within the chamber by supplying the inert gas may need a long time. Also, while the by-products remaining in the chamber are removed, the selective epitaxial process may not be performed in the chamber. Thus, the process may be delayed to deteriorate productivity in the substrate processing process.

### DISCLOSURE OF THE INVENTION

### Technical Problem

The present disclosure provides a substrate processing apparatus capable of quickly cleaning the inside of a chamber and a method of cleaning the chamber.

The present disclosure also provides a substrate processing apparatus capable of improving efficiency of a substrate processing process and a method of cleaning a chamber.

### Technical Solution

In accordance with an exemplary embodiment, a substrate processing apparatus includes: a chamber including a first body part configured to provide a space in which substrates stand by and a second body part configured to provide a space in which a thin film deposition process is performed on each of the substrates; a substrate holder on which the substrates are stacked, the substrate holder being movable between the first body part and the second body part; a first supply unit configured to supply a first gas for depositing a thin film on the substrate in the second body part; a second supply unit configured to supply a second gas, which reacts with by-products generated while the thin film is deposited to generate fume, into the first body part; and an exhaust unit configured to exhaust the gases within the chamber.

The second supply unit may include: a second supply tube configured to define a path through which the second gas flows, the second supply tube being connected to an inner space of the first body part; and a control valve configured to open and close the moving path for the second gas, which is defined in the second supply tube.

The exhaust unit may include: a first exhaust line configured to exhaust the first gas; and a second exhaust line configured to exhaust the second gas and the fume.

The first exhaust line may include: a first exhaust tube communicating with the inside of the chamber; a first exhaust valve configured to open and close a moving path for the first gas, which is defined in the first exhaust tube; and a first exhaust pump connected to the first exhaust tube to provide suction force for suctioning the first gas.

The second exhaust line may include: a second exhaust tube branched from the first exhaust tube; and a second exhaust pump connected to the second exhaust tube to provide suction force for suctioning the second gas or the fume.

The substrate processing apparatus may further include a reaction tube disposed in the second body part, wherein the first supply unit may supply the first gas into the reaction tube.

The second supply unit may supply the second gas into the inside of the first body part or the inside of the reaction tube.

The first gas may include a thin film raw gas and an etching gas.

The by-products may include chlorine (Cl) components, and the second gas may include moisture (H2O).

In accordance with another exemplary embodiment, a method of cleaning a chamber includes: moving a substrate holder into a second body part or a first body part of a chamber after a thin film is deposited on a substrate; supplying a cleaning gas into the first body part; allowing the cleaning gas to react with by-products generated while the thin film is deposited, thereby generating fume; and exhausting the fume from the inside of the chamber to remove the fume.

The moving of the substrate holder into the first body part may include allowing the inside of the first body part of the chamber to communicate with the inside of the second body part of the chamber.

### Advantageous Effects

According to embodiments of the present invention, a cleaning gas (or a second gas) may be supplied into a chamber to intentionally react with by-products. Then, the by-products and the cleaning gas may react with each other to exhaust a generated fume, thereby easily removing the fume from an inside of the chamber. Here, a concentration of the cleaning gas supplied into the chamber may be controlled to slowly generate the fume a little at a time without suddenly generating a large amount of fume within the sealed chamber, thereby exhausting the generated fume. Thus, the fume may be removed while an impact applied to the chamber by the fume is reduced. Thus, a pollution of an environment or equipment due to the sudden generation of the large amount of fume when the chamber is opened may be prevented.

Also, an inside of the chamber may be quickly cleaned when compared to the case in which an inert gas is supplied into the chamber to remove the by-products. Therefore, while the inside of the chamber is cleaned, a standby time for the following selective epitaxial process to be performed in the chamber may be reduced to improve the efficiency in the substrate processing process.

### BRIEF DESCRIPTION OF THE DRAWINGS

FIG. 1 is a schematic view illustrating a structure of substrate processing equipment in accordance with an exemplary embodiment;

FIG. 2 is a view of a substrate processing apparatus in accordance with an exemplary embodiment;

FIG. 3A is a view illustrating a moving path of a first gas in accordance with an exemplary embodiment; and

FIG. 3B is a view illustrating a moving path of a second gas in accordance with an exemplary embodiment.

### MODE FOR CARRYING OUT THE INVENTION

Hereinafter, exemplary embodiments will be described in detail with reference to the accompanying drawings. The present invention may, however, be embodied in different forms and should not be construed as limited to the embodiments set forth herein. Rather, these embodiments are provided so that the present invention will be thorough and complete, and will fully convey the scope of the present invention to those skilled in the art. In the figures, the dimensions of layers and regions are exaggerated for clarity of illustration. Like reference numerals refer to like elements throughout.

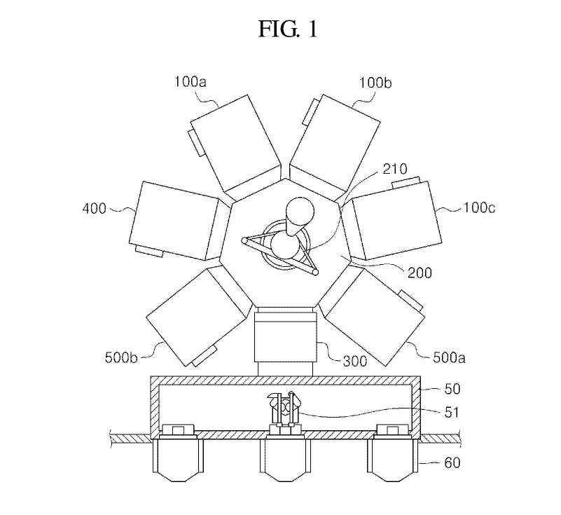

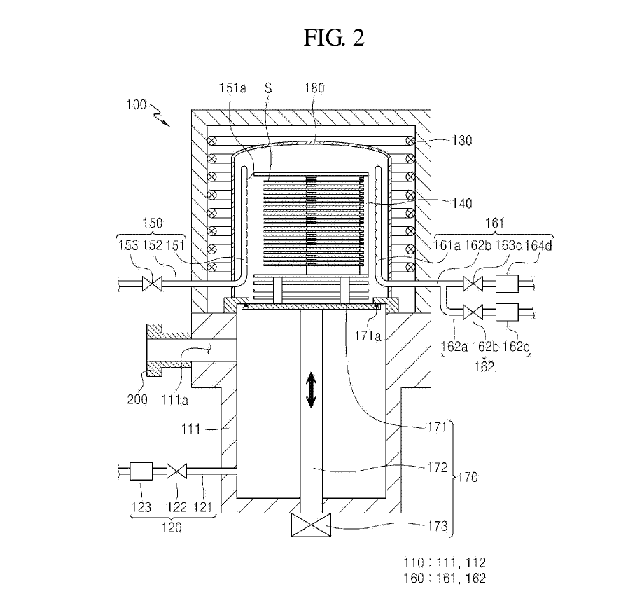

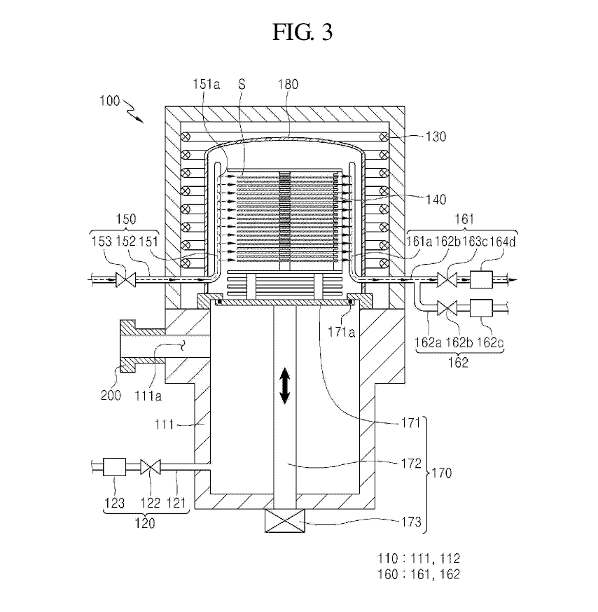

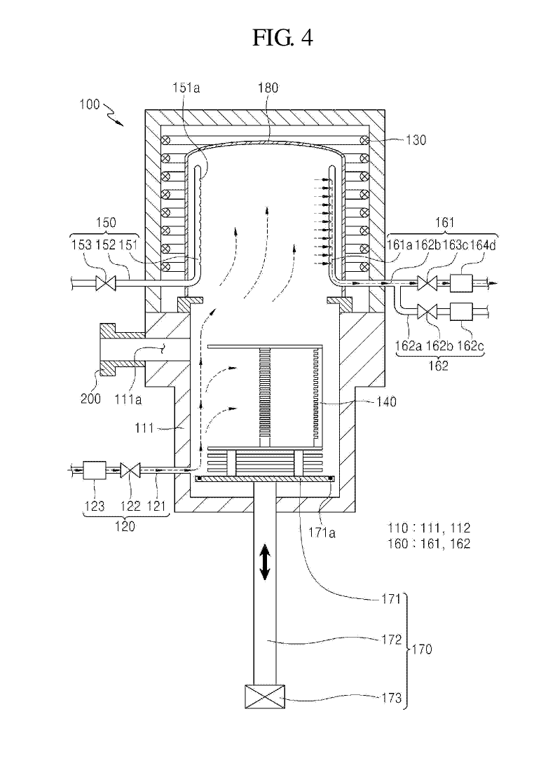

FIG. 1 is a schematic view illustrating a structure of substrate processing equipment in accordance with an exemplary embodiment, FIG. 2 is a view of a substrate processing apparatus in accordance with an exemplary embodiment, FIG. 3A is a view illustrating a moving path of a first gas in accordance with an exemplary embodiment, and FIG. 3B is a view illustrating a moving path of a second gas in accordance with an exemplary embodiment.

A substrate processing apparatus 100 in accordance with an exemplary embodiment includes a chamber 110 including a first body part 111 defining a space in which a substrate S stands by and a second body part 112 defining a space in which a process for forming a thin film on the substrate S is performed, a substrate holder 140 on which the substrate S is loaded and being movable between the first body part 111 and the second body part 112, a first supply unit 150 supplying a first gas to deposit the thin film on the substrate S in the second body part 112, a second supply unit 120 supplying a second gas (or a cleaning gas), which reacts with by-products generated while the thin film is deposited to generate fume into the first body part 111, and an exhaust unit 160 exhausting the gases within the chamber 110.

First, for helping the understanding of the description, a structure of substrate processing equipment in accordance with an exemplary embodiment will be described below. Referring to FIG. 1, substrate processing equipment in accordance with an exemplary embodiment includes cleaning devices 500a and 500b in which an etching process for removing a native oxide layer formed on the substrate is performed, a substrate buffering device 400 in which the plurality of substrates on which the etching process is performed are heated and stand by, and epitaxial devices 100a, 100b, and 100c in which an epitaxial process is performed on the plurality of substrates S on which the heating process is performed. Also, the substrate processing equipment may further include a loadport 60 on which a container (not shown) in which the plurality of substrates S are accommodated is placed, a substrate transfer module 50 disposed adjacent to the loadport 60, a loadlock device 300 that receives the substrates S from the substrate transfer module 50 to maintain an initial vacuum state, and transfer devices 200 disposed between the cleaning devices 500a 500b, the substrate buffering device 400, the epitaxial devices 100a, 100b, and 100c, and a loadlock device 300.

A frame robot 51 for transferring the substrate S between the container placed on the loadport 60 and the loadlock device 300 is disposed in the substrate transfer module 50. Also, a door opener (not shown) for automatically opening and closing a door of the container and a fan filter unit (not shown) for supplying clean air may be disposed in the substrate transfer module 50.

The transfer device 200 includes a transfer chamber defining a space into which the substrate S is loaded and a substrate handler 210 for transferring the substrate S. The transfer chamber has a polygonal planer shape. The transfer chamber has side surfaces that are respectively connected to a loadlock chamber of the loadlock device 300, cleaning chambers of the cleaning devices 500a and 500b, a buffer chamber 110 of the substrate buffering device 400, and epitaxial chambers of the epitaxial devices 100a, 100b, and 100c. Thus, the substrate handler 210 may transfer or carry out the substrate S into or from the loadlock device 300, the cleaning devices 500a and 500b, the substrate buffering device 400, and the epitaxial devices 100a, 100b, and 100c. Also, the transfer chamber may be sealed to be maintained in a vacuum state when the substrate S is transferred. Thus, the substrate S may be prevented from being exposed to contaminants.

The loadlock chamber 300 is disposed between the substrate transfer module 50 and the transfer device 200. The substrate S may temporarily stay in the loadlock chamber of the loadlock device 300 and then be loaded to one of the cleaning devices 500a and 500b, the substrate buffering device 400, and the epitaxial devices 100a, 100b, and 100c by the transfer device 200. The substrate S that is completely processed by the cleaning devices 500a and 500b, the substrate buffering device 400, the epitaxial devices 100a, 100b, and 100c may be unloaded by the transfer device 200 to temporarily stay in the loadlock chamber of the loadlock device 300.

The cleaning devices 500a and 500b may clean the substrate S before the epitaxial process is performed on the substrate S within the epitaxial devices 100a, 100b, and 100c. When the substrate S is exposed to air, the native oxide layer may be formed on a surface of the substrate S. When a surface oxygen content of the substrate S is too high, oxygen atoms may interrupt a crystallographic arrangement of a material to be deposited on the substrate. Thus, the epitaxial process may be affected by harmful influences. As a result, a process for removing the native oxide layer formed on the substrate S may be performed in the cleaning chamber of each of the cleaning devices 500a and 500b.

In the epitaxial devices 100a, 100b, and 100c, the thin film may be formed on the substrate S, and the formed thin film may be adjusted in thickness. In the current embodiment, the three epitaxial devices 100a, 100b, and 100c are provided. Since the epitaxial process requires a relatively long time when compared to that of the cleaning process, manufacturing yield may be improved through the plurality of epitaxial devices 100a, 100b, and 100c. However, the exemplary embodiment is not limited to the number of epitaxial devices 100a, 100b, and 100c. That is, the epitaxial devices may be changed in number. Here, each of the epitaxial devices 100a, 100b, and 100c may be a selective epitaxial device.

The selective epitaxial process may be a process in which the epitaxial thin film is selectively deposited on a desired portion of the top surface of the substrate S. For example, a thin film deposition rate may be different between a pattern formed of oxide or nitride on the substrate S and a surface of the silicon substrate S. Thus, when a thin film raw gas and the etching gas are supplied onto the substrate S, a rate at which the thin film is deposited by the thin film raw gas is quicker than that at which the thin film is etched by the etching gas on a portion (e.g., the surface of the silicon substrate S) on which the thin film is relatively quickly deposited. On the other hand, the rate at which the thin film is deposited by the thin film raw gas is slower than that at which the thin film is etched by the etching gas on a portion (e.g., a surface of the pattern on the substrate S) on which the thin film is relatively slowly deposited. Thus, the epitaxial thin film may be selectively formed on only the surface of the silicon substrate S.

Accordingly, when the selective epitaxial process is performed, the etching gas (e.g., HCl) has to be used together with the thin film raw gas. Since the etching gas contains chlorine (Cl) components, the Cl components may exist in the chamber 110 of the substrate processing apparatus 100 (or the epitaxial device) as by-products after the selective epitaxial process is performed. Thus, when the inside of the chamber 110 is opened immediately after the selective epitaxial process is performed, the Cl component remaining in the chamber 110 as the by-products may react with air introduced into the chamber 110 to suddenly generate a large amount of fume. The fume may cause environmental pollution, corrosion of equipment, safety accidents, and the like. Thus, the substrate processing apparatus 100 (or the epitaxial device) in accordance with an exemplary embodiment may be provided to open the inside of the chamber 110 after quickly removing the by-products within the chamber 110.

Hereinafter, the substrate processing apparatus 100 (or the epitaxial device) in accordance with an exemplary embodiment will be described in detail.

Referring to FIG. 2, the substrate processing apparatus 100 includes a chamber 110 including a first body part 111 and a second body part 112, a substrate holder 140 that is movable between the first body part 111 and the second body part 112, a first supply unit 150 supplying a first gas into the second body part 112, a second supply unit 120 supplying a second gas into the first body part 111, and an exhaust unit 160 exhausting the gases within the chamber 110. Also, the substrate processing apparatus 100 may further include a reaction tube 180, a heating unit 130, and a support unit 170.

The chamber 110 includes the first body part 111 having an inner space and an opened one side and a second body part 112 having an inner space and an opened one side. That is, the opened one side of the first body part 111 and the opened one side of the second body part 112 may be connected to each other to define one chamber 110 having a sealed inner space. For example, the first body part 111 may be disposed at an upper side, and the second body part 112 may be disposed at a lower side. However, an exemplary embodiment is not limited to the above-described positions of the first and second body parts 111 and 112. For example, the first and second body parts 111 and 112 may be changed in position.

The first body part 111 may provide a space in which a plurality of substrates S are accommodated to stand by therein. Since the first body part 111 has the opened upper portion, the first body part 111 may be connected to a lower portion of the second body part 112. Also, an entrance 111a may be defined in a side surface of the first body part 111 so that the substrate S is loaded into or unloaded from the inside of the first body part 111. The first body part 111 may have the entrance 111a in a surface thereof corresponding to the transfer device 200, and the substrate S may be loaded into the first body part 111 from the transfer chamber of the transfer device 200 through the entrance 111a. Thus, the substrate S may be loaded or unloaded into the standby space within the first body part 111 through the entrance 111a defined in the side surface of the first body part 111 in a direction crossing a vertical direction.

Also, a gate valve (not shown) may be disposed between the entrance 111a of the first body part 111 and the transfer chamber of the transfer device 200. The gate valve may isolate the standby space within the first body part 111 from the transfer chamber. Thus, the entrance 111a may be opened and closed by the gate valve. However, an exemplary embodiment is not limited to the structure and shape of the first body part 111. For example, the first body part 111 may have various structures and shapes.

A space in which the plurality of substrates S or the reaction tube 180 are accommodated is defined in the second body part 112. That is, a process for forming a thin film on the substrate S may be performed in the second body part 112 or the reaction tube 180. The second body part 112 may have an opened lower portion. The opened lower portion of the second body 112 may be connected to an upper portion of the first body part 111.

The reaction tube 180 is disposed in the second body part 112. The reaction tube 180 may have an opened lower portion to communicate with the upper portion of the first body part 111. For example, the reaction tube 180 may have a dome shape and be disposed on the upper portion of the first body part 111. Also, a material for forming the reaction tube 180 may include quartz. Since the quartz is a material having superior thermal transfer property, if the reaction tube 180 is formed of the quartz, heat may be easily transferred into the inner space of the reaction tube 180 through the heating unit 130. Also, to prevent the equipment from being corroded by the etching gas supplied onto the substrate S while the selective epitaxial process is performed, the reaction tube 180 may be formed of the quartz. However, an exemplary embodiment is not limited to the structure and shape of the second body part 112. For example, the second body part 112 may have various structures and shapes.

The heating unit 130 is disposed around the outside of the reaction tube 180. The heating unit 130 may supply thermal energy into the reaction tube 180 to heat the substrate S. For example, the heating unit 130 may be disposed between the second body part 112 and the reaction tube 180. Also, the heating unit 130 may be disposed to surround a side surface and an upper portion of the reaction tube 180. Thus, the heating unit 130 may adjust an inner temperature of the reaction tube 180 to easily perform the epitaxial process.

The substrate holder 140 may vertically stack the plurality of substrates S thereon. For example, the plurality of substrates S may be stacked to correspond to multistage stacking spaces (or slots) that are vertically defined in the substrate holder 140. Also, the substrate holder 140 may have a diameter less than an inner diameter of each of the reaction tube 180 and the first body part 111. Thus, the substrate holder 140 may be freely movable between the first body part 111 and the second body part 112 (or between the first body part 111 and the reaction tube 180) in the chamber 110. A plurality of isolation plates (not shown) may be inserted into the slots of the substrate holder 140, respectively. Thus, the stacking spaces in which the substrates S are stacked may be divided by the isolation plates to define spaces in which the substrates are independently processed in each of the stacking spaces. However, an exemplary embodiment is not limited to the structure of the substrate holder 140. For example, the substrate holder 140 may have various structures.

The support unit 170 may be connected to a lower portion of the substrate holder 140 to move the substrate holder 140 in the direction in which the substrates S are stacked. The support unit includes a shaft 172 extending in the stacking direction of the substrates S and having one end connected to the substrate holder 140, a vertically-moving driver 173 connected to the other end of the shaft 172 to vertically move the shaft 172, and a blocking plate 171 disposed on the shaft 172 to block a heating space from the standby space. Also, the support unit 170 may further include a rotating driver (not shown).

The vertically-moving driver 173 may be connected to a lower end of the shaft 172 to vertically move the shaft 172. Thus, the substrate holder 140 connected to the upper end of the shaft 172 may also be vertically moved together with the shaft 172. For example, when the substrate holder 140 is moved downward by an operation of the vertically-moving driver 173, the substrate holder 140 may be disposed in the inner space of the first body part 111. Thus, the substrates S loaded through the entrance of the first body part 111 may be staked on the substrate holder 140 disposed in the first body part 111.

When the plurality of substrates S are completely stacked on the substrate holder 140, the vertically-moving driver 173 may operate to move the substrate holder 140 upward. Thus, the substrate holder 140 may be moved into the inner space of the second body part 112 or the inner space of the reaction tube 180 from the first body part 111. Then, when the blocking plate 171 blocks the inner space of the second body part 112 or the reaction tube 180 from the inner space of the first body part 111, the substrate processing space, e.g., the selective epitaxial process may be performed in the inner space of the second body part 112 or the inner space of the reaction tube 180. However, an exemplary embodiment is not limited to the stacking direction of the substrates S in the substrate holder 140. For example, the stacking direction of the substrates S may be variously changed.

The rotating driver may be connected to a lower portion of the shaft 172 to rotate the substrate holder 140. The rotating driver may rotate the shaft 172 with respect to a vertical central axis of the shaft 172. Thus, when the first gas is supplied onto the substrate S, the first gas may be uniformly supplied onto an entire surface of each of the substrates S stacked on the substrate holder 140 while the substrate holder 140 is rotated.

The blocking plate 171 may seal the inner space of the second body part 112 (or the inner space of the reaction tube 180). The blocking plate 171 may be disposed on the shaft 172. Also, the blocking plate 171 may be disposed on the lower portion of the substrate holder 140 and then be elevated together with the substrate holder 140. The blocking plate 171 may be disposed along a planar shape of the first body part 111. Also, an outer portion of a top surface of the blocking plate 171 may contact the lower portion of the second body part 112 (or the lower portion of the reaction tube 180) to seal the inside of the second body part 112 (or the inside of the reaction tube 180). Thus, when the blocking plate 171 is moved upward, the inside of the second body part 112 (or the inside of the reaction tube 180) may be sealed. When the blocking plate 171 is moved downward, the inside of the second body part 112 (or the inside of the reaction tube 180) may communicate with the inside of the first body part 111.

A sealing member 171a having an O-ring shape may be disposed on a portion of the blocking plate 171, which contacts the second body part 112. The sealing member 171a may block a gap between the blocking plate 171 and the second body part 112 to more effectively seal the heating space. However, an exemplary embodiment is not limited to the structure and shape of the blocking plate 171. For example, the blocking plate 171 may have various structures and shapes.

Referring to FIG. 3A, the first supply unit 150 may supply the first gas from the inside of the second body part 112 (or the inside of the reaction tube 180) to each of the slots of the substrate holder 140. The first supply unit 150 is disposed in the second body part 112 or the reaction tube 180. The first supply unit 150 may include an injection member extending from in the stacking direction of the substrates S, a first supply line 152 supplying the first gas into the injection member 151, and a first gas supply source (not shown) storing the first gas.

The injection member 151 may have a pipe shape that vertically extends. Also, the injection member 151 may have a moving path through which the first gas flows therein. The injection member 151 includes a plurality of injection holes 151a defined in the stacking direction of the substrates S to correspond to the stacking spaces (or the slots) of the substrate holder 140 so as to supply a purge gas onto each of the plurality of substrates S. Thus, when the first gas is supplied into the injection member 151, the first gas may be supplied onto each of the plurality of substrates S within the reaction tube 180 through the plurality of injection holes 151a.

The first supply line 152 may have one end connected to the injection member 151 and the other end connected to the first gas supply source. Thus, the first supply line 152 may supply the first gas within the first gas supply source into the injection member 151. Also, the a flow rate control valve 153 may be disposed in the first supply line 152 to control an amount of first gas supplied from the first gas supply source to the injection member 151. However, an exemplary embodiment is not limited to the structure of the first supply unit 150. For example, the first supply unit 150 may have various structures.

Here, the first gas may be a gas that is used for performing the selective epitaxial process. Thus, the first gas may include at least one of the thin film raw gas, the etching gas, and the carrier gas. That is, the thin film raw gas may be supplied to form a thin film on the substrate S, and the etching gas may be supplied to etch the thin film formed on the substrate S, thereby adjusting a thickness of the thin film. Also, the thin film raw gas and the etching gas may be supplied at the same time to deposit the thin film on a desired area of the substrate S. Here, Cl contained in the etching gas may react with moisture contained in air to generate fume.

Referring to FIG. 3B, the second supply unit 120 communicates with the inside of the first body part 111 of the chamber 110. The second supply unit 120 may supply the second gas into the chamber 110. The second supply unit 120 includes a second supply tube 121 defining a moving path through which the second gas flows and communicating with the inner space of the first body part 111 and a control valve 122 opening and closing the moving path of the second gas, which is defined in the second supply tube 121. Also, the second supply unit 120 may further include a filter 123.

Here, the second gas may be air containing moisture. The second supply unit 120 may supply air into the chamber 110 to allow the air to react with the by-products remaining in the sealed chamber 110. That is, moisture (H2O) within the air may react with the by-products remaining in the chamber after the selective epitaxial process to generate fume that is in a smoke state. However, an exemplary embodiment is not limited to a kind of second gas. For example, various gases containing moisture (H2O) may be used as the second gas.

The second supply tube 121 may have a pipe shape. Also, the second supply tube 121 may have one end connected to the first body part 111 of the chamber 110. For example, the second supply tube 121 may communicate with the lower portion of the first body part 111. The second supply tube 121 may have the other end connected to a suction pump (not shown). Thus, the second gas suctioned into the suction pump may be supplied into the chamber 110 through the second supply tube 121. For example, the suction pump may suction air within a cleaning chamber to supply the suctioned air into the chamber 110. That is, the cleaned air may be supplied into the chamber 110 to minimize introduction of foreign substances into the chamber 110.

The second gas flowing through the second supply tube 121 may be filled from a lower portion of the first body part 111 to fill the inner space of the second body part 112 or the reaction tube 180. That is, the second gas may be filled from the lower portion of the first body part 111 and then be exhausted to the outside of the second body part 112 through the exhaust unit 160 connected to the second body part 112 or the reaction tube 180. Thus, the second gas may be uniformly distributed into the first body part 111 and the second body part 112 or the inner spaces of the first body part 111 and the reaction tube 180 to react with the by-products containing the Cl components remaining in the inner different portions of the chamber 110.

The fume generated by the reaction between the air and the by-products may flow to the exhaust unit 160 along a flow of the second gas flowing though the chamber 110 and then be removed from the inside of the chamber 110. That is, since the by-products react with the fume that is in the smoke state and thus are easily collected, a time taken to remove the by-products within the chamber 110 may be reduced.

The by-products generated in the selective epitaxial process may be generated in the second body part 112 or the reaction tube 180. However, to unload the substrate S, when the substrate holder 140 is moved into the first body part 111, the by-products may be introduced into the first body part 111. Thus, to remove the by-products within the chamber 110, it may be necessary to supply the second gas into the first body part 111 as well as the second body part 112 or the reaction tube 180. Thus, when the second gas is directly supplied into the first body part 111, the second gas may be supplied from the first body part 111. The second gas may flow from the inside of the first body part 111 to the inside of the second body part 112 or the reaction tube 180 and then be uniformly supplied into the chamber 110. However, an exemplary embodiment is not limited to the moving path for the second gas. For example, the second gas may flow through various moving paths.

Also, the supply path for the second gas may be separately provided with respect to the supply path for the first gas. That is, the second gas may react with the Cl components remaining in the supply path for the first gas to contaminate or damage the whole supply path for the first gas. Thus, the supply path for the first gas may be connected to the inside of the second body part 112 or the reaction tube 180, and the supply path for the second gas may be connected to the inside of the first body part 111.

Also, the supply path for the first gas may be connected to the inside of the second body part 112 or the reaction tube 180 so as to be supplied into only the second body part 112 or the reaction tube 180. The supply path for the second gas may be connected to the inside of the first body part 111 so as to be supplied into the whole inside of the chamber 110. Thus, the second gas may be supplied into the first body part 111 and then supplied up to the inside of the second body part 112 or the reaction tube 180.

The control valve 122 is disposed in the second supply tube 121. For example, the control valve 122 may be disposed between the suction pump and an end of the second supply tube 121. The control valve 122 may control an amount of second gas supplied into the chamber 110 through the suction pump. Alternatively, the control valve may open and close the moving path for the second gas, which is defined by the second supply tube 121. Thus, a time point and time at which the second gas is supplied into the chamber 110 may be controlled through the control valve.

The filter 123 may be disposed in the second supply tube 121. For example, the filter 123 may be disposed between the suction pump and the control valve 122. Thus, the filter 123 may filter the second gas supplied into the chamber 110 through the second supply tube 121. That is, when the foreign substances within the second gas are introduced into the chamber 110, the thin film to be formed on the substrate S may be deteriorated in quality by the foreign substances during the selective epitaxial process, and also, the various reaction processes that are performed in the chamber may be interrupted. Thus, to prevent the foreign substances from being introduced into the chamber 110, a filter for filtering the foreign substances within the second gas may be provided. However, an exemplary embodiment is not limited to the structure of the second supply unit 120. For example, the second supply unit 120 may have various structures.

The exhaust unit 160 may exhaust the gases within the chamber 110 to the outside. Thus, the exhaust unit 160 may control flows of the gases within the chamber 110. The exhaust unit 160 may include a first exhaust line 161 through which the first gas is exhausted and a second exhaust line 162 through which the second gas and the fume are exhausted.

The first exhaust line 161 may exhaust the first gas from the inside of the second body part 112 or the reaction tube 180. The first exhaust line 161 may include an exhaust member 161a disposed in the second body part 112 or the reaction tube 180, extending in the stacking direction of the substrates S, and facing the injection member 151, a first exhaust tube 161b connected to the exhaust member 161a to communicate with the inside of the chamber 110 through the exhaust member 161a, and a first exhaust pump 161d connected to the first exhaust tube 161b to provide suction force for suctioning the first gas.

The exhaust member 161a may have a pipe shape that vertically extends. Also, the injection member 151 may have a moving path through which the first gas flows therein. The exhaust member 161a is disposed in the second body part 112 or the reaction tube 180. Also, the exhaust member 161a may include a plurality of exhaust holes, which face the injection hole 151a and are defined in the stacking direction of the substrates S to correspond to the stacking spaces (or the slots) of the substrate holder 140. Thus, the first gas supplied onto the substrate S through the injection hole 151a may be suctioned into the exhaust hole via the substrate S. Thus, the first gas may form the thin film on the substrate S or etch the thin film while passing over the top surface of the substrate S.

The first exhaust tube 161b may have one end connected to the exhaust member 161a and the other end connected to the first exhaust pump 161d. That is, the first exhaust tube 161b may communicate with the inside of the chamber 110 through the exhaust member 161a. Here, the first gas introduced into the exhaust member 161a may be suctioned to the first exhaust pump 161d through the first exhaust tube 161b. Also, a first exhaust valve 161c may be disposed in the first exhaust tube 161b to control an amount of first gas to be exhausted. However, an exemplary embodiment is not limited to the structure of the first exhaust line 161. For example, the first exhaust line 161 may have various structures.

The second exhaust line 162 may exhaust the second gas or the fume. That is, the second exhaust line 162 for separately processing the fume that is capable of contaminating the equipment may be provided to prevent the equipment from being contaminated. The second exhaust line 162 may include a second exhaust tube 162a branched from the first exhaust tube 161b, a second exhaust valve 162b disposed in the second exhaust tube to open and close the moving path through which the second gas or the fume flows, a second exhaust pump 162c connected to the second exhaust tube 162a to provide suction force for suctioning the second gas or the fume, and a purifier (not shown) for removing or purifying the fume.

The second exhaust tube 162a may have one end connected to the first exhaust tube 161b and the other end connected to the second exhaust pump 162c. For example, the second exhaust tube 162a may be connected to the first exhaust tube 161b between the exhaust member 161a and the first exhaust valve 161c. Thus, the second gas or the fume suctioned through the exhaust member 161a may be introduced into the second exhaust tube 162a.

Here, the second gas introduced into the second exhaust tube 162a may pass through a portion of the exhaust member 161a and the first exhaust tube 161b. Thus, the second gas may react with a portion of the by-products remaining in the exhaust member 161a and the first exhaust tube 161b to generate the fume. Thus, the by-products within the portions of the insides of the exhaust member 161a and the first exhaust tube 161b, through which the second gas passes, may be removed to clean the insides of the exhaust member 161a and the second exhaust tube 161b. However, an exemplary embodiment is not limited to the connection structure of the second exhaust tube 162a. For example, the second exhaust tube 162a may have various connection structures. That is, the second exhaust tube 162a may have one end that directly communicates with the inside of the second body part 112 or the reaction tube 180.

The second exhaust valve 162b may be disposed in the second exhaust tube 162a. For example, the second exhaust valve 162b may be disposed between the one end of the second exhaust tube 162a and the second exhaust pump. Thus, the second exhaust valve 162b may control a flow rate of each of the gases introduced into the second exhaust tube 162a via the first exhaust tube 161b after being introduced into the exhaust member 161a.

Thus, when the epitaxial process is performed, the second exhaust valve 162b may be closed, and the first exhaust valve 161c may be opened. As a result, the first gas used for the epitaxial process may be prevented from flowing to the second exhaust valve 162b through the second exhaust tube 162a and thus flow to the first exhaust pump 161d through the first exhaust tube 161b. When the cleaning process for removing the by-products within the chamber 110 is performed after the selective epitaxial process, the second exhaust valve 162b may be opened, and the first exhaust valve 161c may be closed. As a result, the second gas supplied into the chamber 110 may be prevented from flowing to the first exhaust pump 161d through the first exhaust tube 161b and thus flow to the second exhaust pump 162c through the second exhaust tube 162a. That is, the first exhaust valve 161c and the second exhaust valve 162b may be controlled to select the moving paths for the gases according to the processes.

The second exhaust pump 162c may be connected to the second exhaust tube 162a to provide suction force for suctioning the second gas and the fume. The second exhaust pump 162c may provide suction force for the gases in addition to the suction force of the first exhaust pump 161d. The first exhaust pump 161d may be connected to other devices in addition to the substrate processing apparatus 100 (or the epitaxial device), e.g., the loadlock device 300, the cleaning devices 500a and 500b, and the substrate buffering device 400. Alternatively, the first exhaust pump 161d may be connected to other epitaxial devices 100b and 100c in addition to the substrate processing apparatus 100a in according to an exemplary embodiment. That is, the first exhaust pump 161d may serve as a main pump for adjusting an inner pressure of each of the devices provided in the substrate processing equipment. Thus, when the second gas, e.g., air is suctioned into the first exhaust pump 161d, all the inner pressures of other devices except for the substrate processing apparatus 100 may be adjusted to an atmosphere pressure. Alternatively, when the fume is introduced into the first exhaust pump 161d, the insides of other devices may be contaminated by the fume. Thus, the second exhaust pump 162c may be separately provided to independently control the inner pressure of the substrate processing apparatus 100 and the inner pressures of other devices.

The second exhaust pump 162c may move the fume suctioned from the inside of the chamber 110 to the purifier. That is, when the fume is discharged to the outside, the fume may contaminate the environments, damage the equipment, and cause injury to a worker. Thus, the process for removing or purifying the fume may be performed by using the purifier. However, an exemplary embodiment is not limited to the structure of the second exhaust line 162. For example, the second exhaust line 162 may have various structures.

As described above, the cleaning gas (or the second gas) may be supplied into the chamber 110 to intentionally react with the by-products. Then, the by-products and the cleaning gas may react with each other to exhaust the generated fume, thereby easily removing the fume from the inside of the chamber 110. Here, the concentration of the cleaning gas supplied into the chamber 110 may be controlled to slowly generate the fume a little without suddenly generating a large amount of fume within the sealed chamber 110, thereby exhausting the generated fume. Thus, the fume may be removed while the impact applied to the chamber 110 by the fume is reduced. Thus, the pollution of the environment or equipment due to the sudden generation of the large amount of fume when the chamber 110 is opened may be prevented.

Also, the inside of the chamber 110 may be quickly cleaned when compared to the case in which the inert gas is supplied into the chamber 110 to remove the by-products. Therefore, while the inside of the chamber 110 is cleaned, the standby time for the following selective epitaxial process to be performed in the chamber 110 may be reduced to improve the efficiency in the substrate processing process.

Hereinafter, a method of cleaning the chamber in accordance with an exemplary embodiment will be described in detail.

A method of cleaning the chamber in accordance with an exemplary embodiment may include a process of moving a substrate holder from the inside of a second body part to the inside of a first body part after a thin film is deposited on a substrate, a process of supplying a cleaning gas into the first body part, a process of allowing the cleaning gas to react with by-products within the chamber, thereby to generate fume, and a process of removing the fume from the inside of the chamber. Here, the by-products may include Cl components, and the cleaning gas may contain moisture (H2O).

After the process of depositing the thin film on the substrate, e.g., a selective epitaxial process, the by-products generated during the selective epitaxial process may remain in the chamber 110 of the substrate processing apparatus 100. Thus, when the chamber 110 is opened immediately after the selective epitaxial process is performed, the Cl component remaining in the chamber 110 as the by-products may react with moisture contained in air introduced into the chamber 110 to suddenly generate a large amount of fume. The fume discharged to the outside of the chamber 110 may cause environmental pollution, corrosion of equipment, safety accidents, and the like. Thus, when the inside of the chamber 110 is opened for inspecting or repairing, the cleaning process for removing the by-products within the chamber 110 has to be performed before the inside of the chamber 110 is opened. Here, the cleaning process may be performed on the substrates S stacked on a substrate holder 140 after all the substrates S are unloaded to the outside of the chamber 110.

The substrate holder 140 is moved into a first body part 111 disposed under a second body part 112. That is, when the substrate holder 140 is moved upward, the blocking plate 171 disposed on a lower portion of the substrate holder 140 may block the inside of the second body part 112 from the inside of the first body part 111 or the inside of a reaction tube 180 from the inside of the first body part 111. Thus, when the substrate holder 140 is moved downward, the blocking plate 171 may also be moved downward together with the substrate holder 140 to allow the inside of the second body part 112 to communicate with the inside of the first body part 111 or allow the inside of the reaction tube 180 to communicate with the inside of the first body part 111. Thus, when a second gas is supplied into the first body part 111, the second gas may be supplied into the entire inner space of the first and second body parts 111 and 112 or the reaction tube 180.

Then, an N2 gas may be supplied into the chamber 110 to increase an inner pressure of the chamber 110, which is maintained in a vacuum state during the selective epitaxial process. That is, the inner pressure of the chamber 110 is increased to a predetermined pressure value through the N2 gas, and then, the cleaning gas may be supplied into the chamber 110 to perform the cleaning process in the chamber 110. Alternatively, the N2 gas and the cleaning gas may be supplied into the chamber 110 at the same time. Thus, the cleaning process in the chamber may be performed simultaneously while increasing the inner pressure of the chamber 110.

Here, when an inner space of the chamber 110 is sealed by a separate coupling member (not shown) or a sealing member (not shown), the inner pressure of the chamber 110 may increase to the atmosphere pressure or more to perform the cleaning process in the chamber 110. When the inner space of the chamber 110 is sealed by a pressure less than that of the outside without having the separate coupling member or the sealing member, the inner pressure of the chamber 110 may increase to a pressure less than the atmosphere pressure to perform the cleaning process in the chamber 110. However, an exemplary embodiment is not limited to the inner pressure of the chamber 110 during the cleaning process. For example, the inner space of the chamber 110 may be changed.

After the selective epitaxial process, by-products due to the selective epitaxial process may remain in the second body part 112 or the reaction tube 180. Also, after the selective epitaxial process, since the substrate S is unloaded after the substrate S is moved into the first body part 111, the by-products may be introduced into the inner space of the first body part 111. Thus, when the inside of the chamber 110 is cleaned, it may be necessary to clean the inner space of the first body part 111 in addition to the inner space of the second body part 112 or the reaction tube 180. Thus, after the inside of the first body part 111 communicates with the inside of the second body part 112 or the inside of the reaction tube 180, a second gas, i.e., a cleaning gas may be supplied into the chamber 110.

After the substrate holder 140 is moved into the first body part 111, the second gas may be supplied into the first body part 111. The second gas introduced into the first body part 111 may be filled up to the insides of the first and second body parts 111 and 112 or the inside of the reaction tube 180 and thus be uniformly distributed into the inner space of the chamber 110. Then, the second gas may be exhausted to the outside of the chamber 110 through an exhaust unit 160 communicating with the inside of the second body part 112 or the inside of the reaction tube 180. The second gas may react with the by-products remaining in the chamber 110. For example, the by-products may contain Cl components, and the Cl components may react with moisture (H2O) within the second gas to generate fume.

Here, a concentration of the second gas within the chamber 110 may be controlled to generate the fume a little at a time in the sealed chamber 110, thereby exhausting the generated fume. For example, when an inert gas is supplied into the chamber 110 to increase the inner pressure of the chamber 110 and then receive the second gas, the second gas may slowly increase in concentration while a concentration of the inert gas within the chamber 110 slowly decreases. That is, a large amount of second gas is prevented from being supplied into the chamber 110 at a time by using the inert gas. Thus, a concentration of the moisture existing in the chamber 110 may increase in stages to prevent a large amount of fume from being generated in the chamber 110.

When the inert gas and the second gas are supplied at the same time, an amount of inert gas to be supplied may be adjusted to control the concentration of the moisture within the chamber 110. That is, when the supply amount of inert gas increases, the moisture contained in the gases within the chamber 110 may decrease in concentration. Thus, since an amount of moisture that reacts with the Cl component within the chamber 110 is less, the large amount of fume may be prevented from being suddenly generated in the chamber 110. On the other hand, when the supply amount of inert gas decreases, the moisture contained in the gases within the chamber 110 may increase to increase the generation of the fume. Thus, the supply amount of inert gas may be adjusted to control the amount of fume to be generated. As a result, the fume may be stably generated in the chamber and then be exhausted.

Since the fume exists in the smoke state, the fume may be more easily exhausted through the exhaust unit 160 when compared that the fume exists as the by-products. Here, since the second gas is continuously introduced into the exhaust unit 160, the fume may be introduced into the exhaust unit 160 together with the second gas along the flow of the second gas. Thus, the by-products remaining in the chamber 110 may be quickly removed. The fume collected as described above may be purified through a purifier. Thus, the contamination due to the leakage of the fume may be prevented.

Then, the inside of the chamber 110 may be opened. Here, the operating state of the exhaust unit 160 may be continuously maintained. Thus, even though the inside of the chamber 110 is opened, the fume remaining in the chamber 110 may be introduced into the exhaust unit 160 without being exhausted to the outside of the chamber 110. Thus, the leakage of the fume to the outside may be prevented.

As described above, the cleaning gas (or the second gas) may be supplied into the chamber 110 to intentionally react with the by-products. Then, the by-products and the cleaning gas may react with each other to exhaust the generated fume, thereby easily removing the fume from the inside of the chamber 110. Here, the concentration of the cleaning gas supplied into the chamber 110 may be controlled to slowly generate the fume a little at a time without suddenly generating a large amount of fume within the sealed chamber 110, thereby exhausting the generated fume. Thus, the fume may be removed while the impact applied to the chamber 110 by the fume is reduced. Thus, the pollution of the environment or equipment due to the sudden generation of the large amount of fume when the chamber 110 is opened may be prevented.

Also, the inside of the chamber 110 may be quickly cleaned when compared to the case in which the inert gas is supplied into the chamber 110 to remove the by-products. Therefore, while the inside of the chamber 110 is cleaned, the standby time for the following selective epitaxial process to be performed in the chamber 110 may be reduced to improve the efficiency in the substrate processing process.

As described above, while this invention has been particularly shown and described with reference to preferred embodiments thereof, it will be understood by those skilled in the art that various changes in form and details may be made therein without departing from the spirit and scope of the invention as defined by the appended claims. Therefore, the scope of the invention is defined not by the detailed description of the invention but by the appended claims, and all differences within the scope will be construed as being included in the present invention.

1. A substrate processing apparatus comprising:
a chamber comprising a first body part configured to provide a space in which substrates stand by and a second body part configured to provide a space in which a thin film deposition process is performed on each of the substrates;
a substrate holder on which the substrates are stacked, the substrate holder being movable between the first body part and the second body part;
a first supply unit configured to supply a first gas for depositing a thin film on the substrate in the second body part;
a second supply unit configured to supply a second gas, which reacts with by-products generated while the thin film is deposited to generate fume, into the first body part; and
an exhaust unit configured to exhaust the gases within the chamber.

2. The substrate processing apparatus of claim 1, wherein the second supply unit comprises:
a second supply tube configured to define a path through which the second gas flows, the second supply tube being connected to an inner space of the first body part; and
a control valve configured to open and close the moving path for the second gas, which is defined in the second supply tube.

3. The substrate processing apparatus of claim 1, wherein the exhaust unit comprises:
a first exhaust line configured to exhaust the first gas; and
a second exhaust line configured to exhaust the second gas and the fume.

4. The substrate processing apparatus of claim 3, wherein the first exhaust line comprises:
a first exhaust tube communicating with the inside of the chamber;
a first exhaust valve configured to open and close a moving path for the first gas, which is defined in the first exhaust tube; and
a first exhaust pump connected to the first exhaust tube to provide suction force for suctioning the first gas.

5. The substrate processing apparatus of claim 4, wherein the second exhaust line comprises:
a second exhaust tube branched from the first exhaust tube; and
a second exhaust pump connected to the second exhaust tube to provide suction force for suctioning the second gas or the fume.

6. The substrate processing apparatus of claim 1, further comprising a reaction tube disposed in the second body part,
wherein the first supply unit supplies the first gas into the reaction tube.

7. The substrate processing apparatus of claim 6, wherein the second supply unit supplies the second gas into the inside of the first body part or the inside of the reaction tube.

8. The substrate processing apparatus of claim 1, wherein the first gas comprises a thin film raw gas and an etching gas.

9. The substrate processing apparatus of claim 8, wherein the by-products comprise chlorine (Cl) components, and
the second gas comprises moisture (H2O).

10. A method of cleaning a chamber, the method comprising:
moving a substrate holder into a second body part or a first body part of a chamber after a thin film is deposited on a substrate;
supplying a cleaning gas into the first body part;
allowing the cleaning gas to react with by-products generated while the thin film is deposited, thereby generating fume; and
exhausting the fume from the inside of the chamber to remove the fume.

11. The method of claim 10, wherein the moving of the substrate holder into the first body part comprises allowing the inside of the first body part of the chamber to communicate with the inside of the second body part of the chamber.
